(19) United States
(12) Patent Application Publication
(10) Pub. No.: US 2026/0040738 A1
(43) Pub. Date: Feb. 5, 2026

(54) ELECTRONIC DEVICE AND MANUFACTURING METHOD THEREOF

(71) Applicant: InnoLux Corporation, Miao-Li County (TW)

(72) Inventors: Sin-Hua YANG, Miao-Li County (TW); Chiung-Chieh KUO, Miao-Li County (TW); Kuan-Hung KUO, Miao-Li County (TW)

(73) Assignee: InnoLux Corporation, Miao-Li County (TW)

(21) Appl. No.: 19/262,112

(22) Filed: Jul. 8, 2025

(30) Foreign Application Priority Data
Aug. 1, 2024 (CN) 202411047082.5

(51) Int. Cl. H10H 29/02; H01L 21/66; H10H 29/01

(52) U.S. Cl. CPC H10H 29/02; H01L 22/22; H10H 29/012

(57) ABSTRACT

A manufacturing method of an electronic device includes following steps: (a) providing an electronic panel, wherein the electronic panel includes a first substrate and a plurality of electronic elements, and the plurality of electronic elements are bonded on the first substrate; (b) inspecting the electronic panel, wherein when the electronic panel is determined to be a defective product, perform following step (c) to step (f); (c) debonding the plurality of electronic elements from the first substrate; (d) transferring the plurality of electronic elements to a temporary substrate; (e) transferring the plurality of electronic elements from the temporary substrate to a second substrate; and (f) bonding the plurality of electronic elements on the second substrate.

### BACKGROUND OF THE DISCLOSURE

### 1. Field of the Disclosure

The present disclosure relates to an electronic device and a manufacturing method thereof, and more particularly to an electronic device including microelectronic units and a manufacturing method thereof.

### 2. Description of the Prior Art

Micro light emitting diodes may be transferred to a target substrate through mass transfer process. However, after transferring the micro light emitting diodes to the target substrate, if it is detected that the target substrate is a defective product, or an error occurs in the subsequent process to make the product defective, the target substrate and the micro light emitting diodes disposed thereon will be scrapped together. Therefore, not only the production cost of electronic device is increased, the carbon emissions may also increase. Accordingly, to solve the above-mentioned problems is still an important issue in the present field.

### SUMMARY OF THE DISCLOSURE

The present disclosure aims at providing an electronic device including recycled light emitting diodes and a manufacturing method of an electronic device using recycled light emitting diodes.

A manufacturing method of an electronic device is provided by the present disclosure, wherein the manufacturing method includes following steps: (a) providing an electronic panel, wherein the electronic panel includes a first substrate and a plurality of electronic elements, and the plurality of electronic elements are bonded on the first substrate; (b) inspecting the electronic panel, wherein when the electronic panel is determined to be a defective product, perform following step (c) to step (f); (c) debonding the plurality of electronic elements from the first substrate; (d) transferring the plurality of electronic elements to a temporary substrate; (e) transferring the plurality of electronic elements from the temporary substrate to a second substrate; and (f) bonding the plurality of electronic elements on the second substrate.

An electronic device is provided by the present disclosure, wherein the electronic device includes a substrate and a plurality of electronic elements bonded on the substrate. The plurality of electronic element include a first electronic element and a second electronic element, the first electronic element has a height H1, the second electronic element has a height H2, the height H2 is greater than the height H1, and the height H1 and the height H2 satisfy:

0.05≤(H2−H1)/H2≤1.1.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 shows a flow chart of a manufacturing method of an electronic device according to a first embodiment of the present disclosure.

FIG. 2 to FIG. 3 schematically illustrate a manufacturing process of the electronic device according to the first embodiment of the present disclosure.

FIG. 4 schematically illustrates bonding ways of an electronic element according to the first embodiment of the present disclosure.

FIG. 5 schematically illustrates bonding ways of an electronic element according to a variant embodiment of the first embodiment of the present disclosure.

FIG. 6 schematically illustrates a manufacturing process of an electronic device according to a second embodiment of the present disclosure.

FIG. 7 schematically illustrates a manufacturing process of an electronic device according to a third embodiment of the present disclosure.

FIG. 8 schematically illustrates a manufacturing process of an electronic device according to a fourth embodiment of the present disclosure.

FIG. 9 schematically illustrates a manufacturing process of an electronic device according to a fifth embodiment of the present disclosure.

FIG. 10 schematically illustrates a manufacturing process of an electronic device according to a sixth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a back-light device, an antenna device, a tiled device, a virtual reality product or other suitable electronic devices, but not limited thereto. The electronic device of the present disclosure may be a foldable electronic device, a flexible electronic device or a stretchable electronic device. The display device may include a non-self-emissive display device or a self-emissive display device. The non-self-emissive display device for example includes a liquid crystal display device, but not limited thereto. The self-emissive display device for example includes a light emitting diode display device, but not limited thereto. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include passive elements or active elements, such as capacitor, resistor, inductor, diode, transistor, sensors, and the like. The diode may include a light emitting diode or a photo diode. The light emitting diode may for example include an organic light emitting diode (OLED) or an inorganic light emitting diode. The inorganic light emitting diode may for example include a mini light emitting diode (mini LED), a micro light emitting diode (micro LED) or a quantum dot light emitting diode (QLED), but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices. The display device is taken as an example of the electronic device for describing the contents of the present disclosure in the following, but the present disclosure is not limited thereto. The electronic device of the present disclosure may be combinations of the above-mentioned devices, such as the combination of display device and other devices, but not limited thereto.

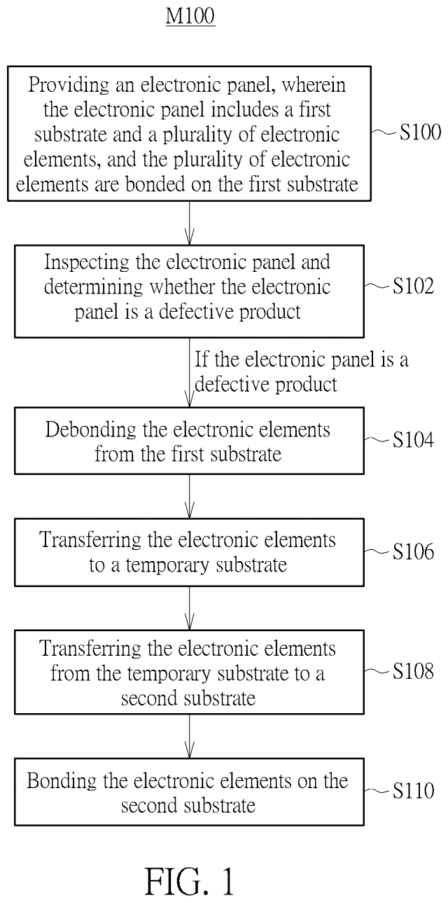

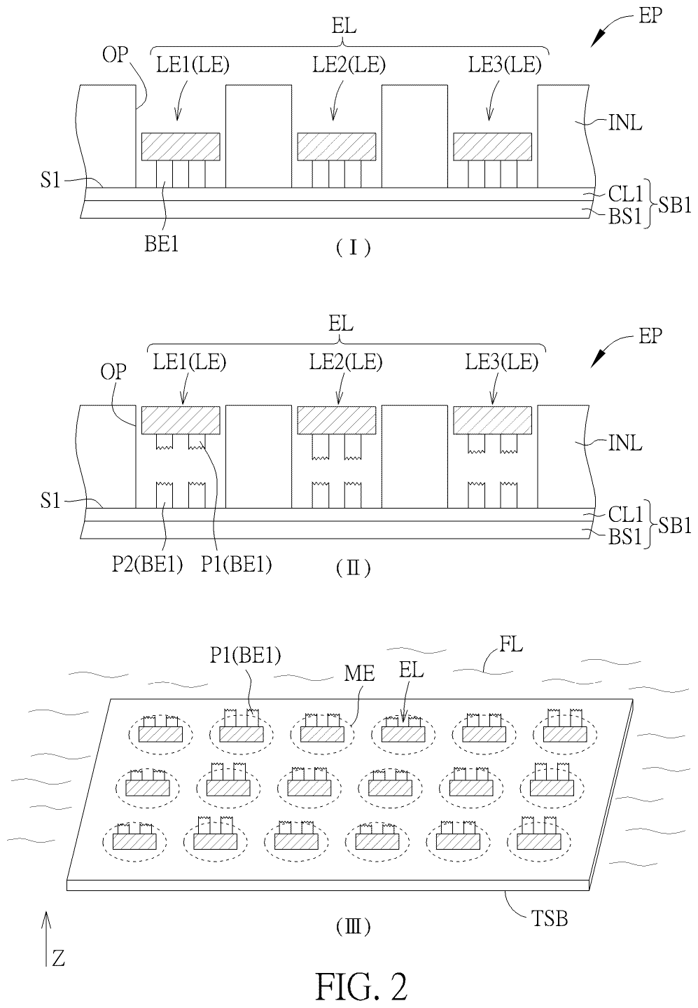

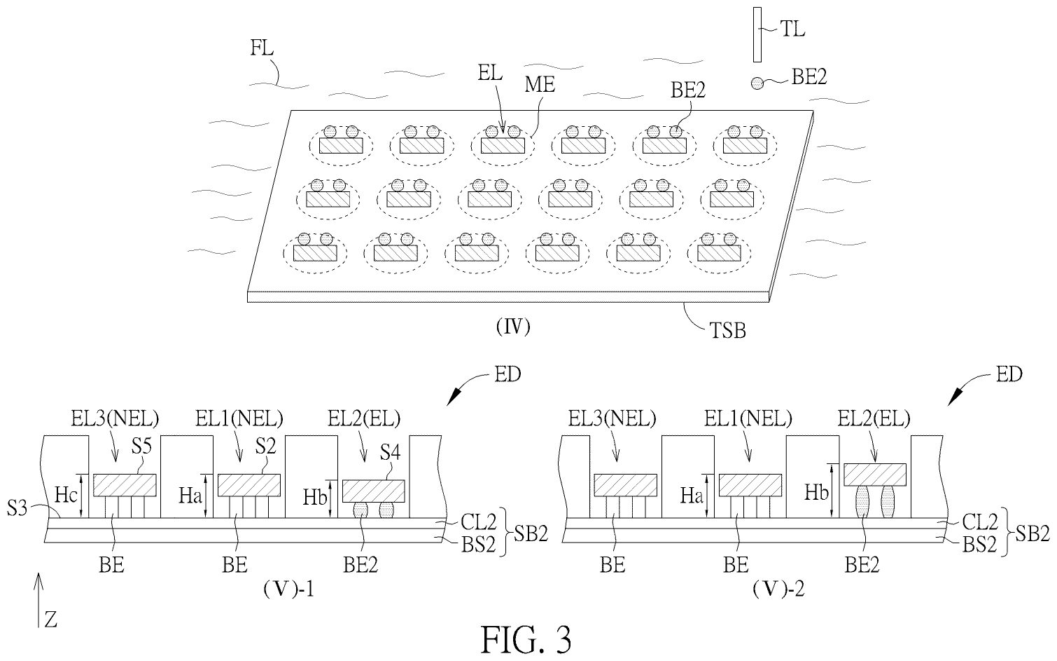

Referring to FIG. 1 to FIG. 3, FIG. 1 shows a flow chart of a manufacturing method of an electronic device according to a first embodiment of the present disclosure, FIG. 2 to FIG. 3 schematically illustrate a manufacturing process of the electronic device according to the first embodiment of the present disclosure. Specifically, FIG. 1 to FIG. 3 show a method of recycling electronic elements and manufacturing an electronic device using the recycled electronic elements. According to the present embodiment, the manufacturing method M100 of the electronic device ED (shown in FIG. 3) may include following steps:
S100: providing an electronic panel, wherein the electronic panel includes a first substrate and a plurality of electronic elements, and the plurality of electronic elements are bonded on the first substrate;
S102: inspecting the electronic panel and determining whether the electronic panel is a defective product, wherein when the electronic panel is determined to be a defective product, perform following step S104 to step S110;
S104: debonding the electronic elements from the first substrate;
S106: transferring the electronic elements to a temporary substrate;
S108: transferring the electronic elements from the temporary substrate to a second substrate; and
S110: bonding the electronic elements on the second substrate.

The steps in the manufacturing method M100 of the electronic device ED will be detailed in the following.

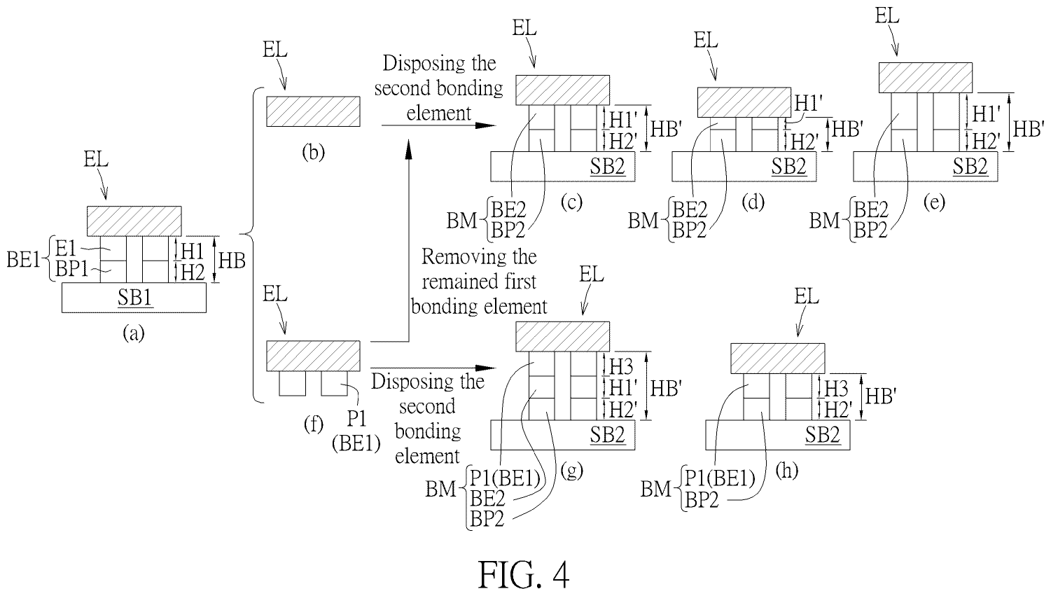

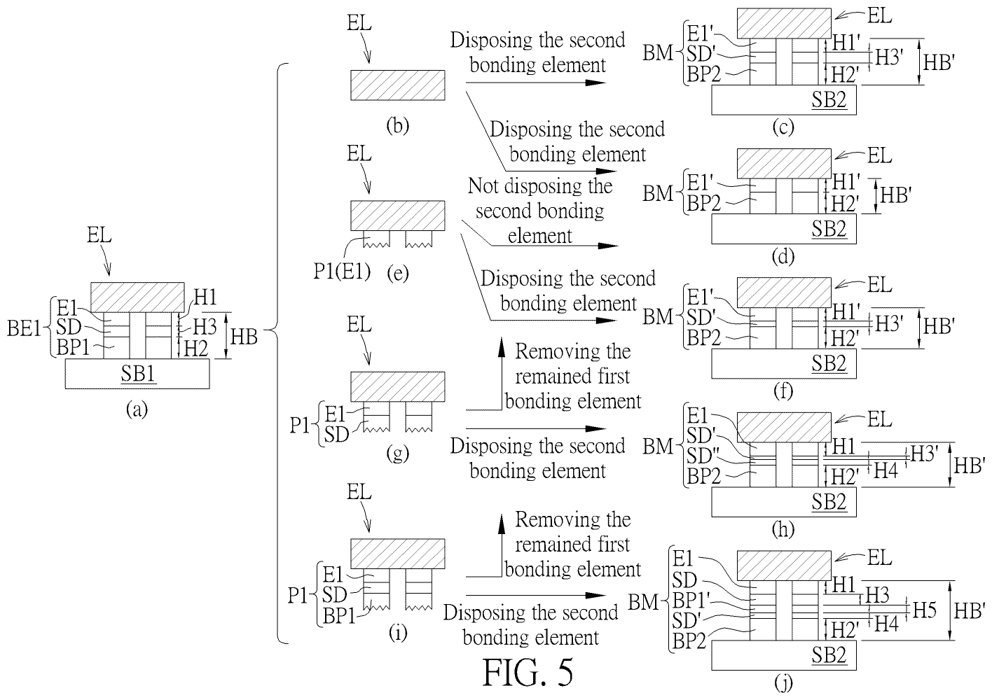

The manufacturing method M100 of the electronic device ED may include the step S100: providing an electronic panel EP at first. As shown in the process (I) of FIG. 2, the electronic panel EP includes a first substrate SB1 and a plurality of electronic elements EL, wherein the plurality of electronic elements EL may be disposed on the first substrate SB1 and bonded on the first substrate SB1. The first substrate SB1 may include a base BS1 and a circuit layer CL1 disposed on the base BS1. The base BS1 may include a rigid base or a flexible base. The rigid base for example includes glass, quartz, sapphire, ceramic, other suitable materials or combinations of the above-mentioned materials, and the flexible base for example includes polyimide (PI), polycarbonate (PC), polyethylene terephthalate (PET), other suitable materials or combinations of the above-mentioned materials, but not limited thereto. The circuit layer CL1 may include various kinds of wires, circuits or electronic units (such as active elements and/or passive elements) that can be applied to the electronic panel EP, but not limited thereto. For example, the circuit layer CL1 may include driving units, wherein the driving units may be electrically connected to the electronic elements EL disposed on the first substrate SB1, thereby driving the electronic elements EL, but not limited thereto. The driving unit may for example include thin film transistor (TFT) elements or micro integrated circuits (micro IC), but not limited thereto. In such condition, although it is not shown in the figure, the circuit layer CL1 may include elements and/or layers such as semiconductor layers, gate electrodes, source electrodes, drain electrodes, and the like to form the driving units, but not limited thereto. The circuit layer CL1 may further include other suitable elements and/or layers, which is not limited to the elements and/or the layers mentioned above. In the present embodiment, the circuit layer CL1 may have a plurality of bonding pads (not shown in the figure, such as the bonding pad BP1 shown in FIG. 4 and FIG. 5) on a surface S1 away from the base BS1, and the plurality of bonding pads may be electrically connected to the driving units in the circuit layer CL1, wherein the electronic elements EL may be electrically connected to the plurality of bonding pads, thereby being electrically connected to the driving units. In other embodiments, the electronic elements EL may be bonded on the first substrate SB1 through other suitable ways, which is not limited to the method mentioned above.

In some embodiments, as shown in the process (I) of FIG. 2, the first substrate SB1 may further include an insulating layer INL disposed on the circuit layer CL1. The insulating layer INL may be disposed on the side of the circuit layer CL1 opposite to the base BS1. The insulating layer INL may include a plurality of openings OP or may define a plurality of openings OP, and the electronic elements EL may be disposed in the plurality of openings OP. The openings OP may expose the bonding pads on the surface S1 of the circuit layer CL1, such that the electronic elements EL disposed in the openings OP may contact the bonding pads. The insulating layer INL may include any suitable insulating material.

The electronic element EL may include any suitable element according to the type or use of the electronic panel EP. For example, the electronic panel EP of the present embodiment may include a display panel, and the electronic elements EL may include light emitting elements LE. As shown in the process (I) of FIG. 2, the light emitting elements LE may include a first light emitting element LE1, a second light emitting element LE2 and a third light emitting element LE3, but not limited thereto. The light emitting element may include a light emitting diode, but not limited thereto. The light emitting diode may include an organic light emitting diode (OLED), a quantum dot light emitting diode (QLED), an inorganic light emitting diode or combinations thereof. The inorganic light emitting diode may for example include a mini light emitting diode (mini LED) or a micro light emitting diode (micro LED), but not limited thereto. For example, the electronic element EL may include a micro light emitting diode, but not limited thereto. In such condition, the insulating layer INL may serve as a pixel defining layer PDL. It should be noted that the electronic element EL may include any suitable semiconductor element, which is not limited to the elements mentioned above. In some embodiments, the electronic panel EP may include a sensing panel. In such condition, the electronic element EL may include any suitable sensing unit, such as photo diode, but not limited thereto. In some embodiments, the electronic panel EP may include combinations of display panel and other electronic devices. It should be noted that, the electronic panel EP may further include other layers and/or elements, which is not limited to what is shown in FIG. 2.

In the present embodiment, the light emitting elements LE may have the same color and the same appearance. “The light emitting elements LE having the same color” described herein may represent that the light emitting elements LE emit lights of the same color. Specifically, the first light emitting element LE1, the second light emitting element LE2 and the third light emitting element LE3 shown in the process (I) of FIG. 2 may emit lights of the same color, such as blue lights, but not limited thereto. “The light emitting elements LE having the same appearance” described above may represent that the light emitting elements LE have the same shape and the same size. “The shape of the light emitting element LE” described herein may for example be the shape of the light emitting element LE in a top view direction (that is, a direction parallel to the direction Z), or the shape of the projection of the light emitting element LE on the first substrate SB1, but not limited thereto. “The size of the light emitting element LE” may be the volume, the length or the width of the light emitting element LE, or the area of the projection of the light emitting element LE on the first substrate SB1. In the present embodiment, “the light emitting elements LE having the same appearance” may include the embodiments that the projections of the light emitting elements LE on the first substrate SB1 have the same area and the same shape, but not limited thereto. It should be noted that although it is not shown in FIG. 2, the electronic panel EP may include more light emitting elements LE, and these light emitting elements LE may have the same color and the same appearance.

After the electronic panel EP is provided, the step S102 may be performed to inspect the electronic panel EP and determine whether the electronic panel EP is a defective product. Specifically, “determining whether the electronic panel EP is a defective product” in the step S102 may include the embodiments of determining whether the first substrate SB1 of the electronic panel EP is a defective product. Specifically, the electronic panel EP may be inspected through any suitable way to determine whether the first substrate SB1 of the electronic panel EP is abnormal, and when the first substrate SB1 is determined to be abnormal after inspection, the electronic panel EP may be determined to be a defective product. “The first substrate SB1 is abnormal” mentioned above may include the situations that the first substrate SB1 cannot be operated normally or the first substrate SB1 is damaged, such as the situation that the wire in the circuit layer CL1 is short-circuited or disconnected, causing the electronic element EL bonded on the first substrate SB1 to fail to work, or the situation that some of the layers of the first substrate SB1 are damaged, but not limited thereto. In such condition, since the electronic elements EL bonded on the first substrate SB1 are not damaged, the electronic elements EL may be recycled through the following steps in the manufacturing method M100, and the recycled electronic elements EL may serve as the electronic elements in the electronic device ED formed in the subsequent process.

When the electronic panel EP is determined to be a defective product, the step S104 may be performed to debond the electronic elements EL from the first substrate SB1. Specifically, as shown in the process (II) of FIG. 2, the step of debonding the electronic elements EL and the first substrate SB1 may include breaking the first bonding elements BE1 between the electronic elements EL and the first substrate SB1. The first bonding elements BE1 may be located between the electronic elements EL and the first substrate SB1, and the electronic elements EL may be electrically connected to the first substrate SB1 through the first bonding elements BE1. In the present embodiment, the first bonding element BE1 may include a set of conductive layers that electrically connect the electronic element EL to the first substrate SB1 (or the circuit layer CL1 of the first substrate SB1). For example, the first bonding elements BE1 may include the electrodes on the surface of the electronic elements EL, the bonding pads on the surface of the circuit layer CL1 and/or the solder balls located between the electrodes and the bonding pads, wherein the detail thereof may refer to FIG. 4, FIG. 5 and following contents. The breaking of the first bonding elements BE1 may for example be performed by laser process, etching process or other suitable processes, based on the bonding way of the electronic elements EL and the first substrate SB1. In some embodiments, when the electronic elements EL are bonded on the first substrate SB1 through laser bonding, the first bonding elements BE1 between the electronic elements EL and the first substrate SB1 may be broken by a laser process. In some embodiments, when the electronic elements EL are bonded on the first substrate SB1 through eutectic bonding (such as Cu—Cu bonding), the first bonding elements BE1 between the electronic elements EL and the first substrate SB1 may be broken by an etching process. In some embodiments, the first bonding elements BE1 may be broken through other ways. In the present embodiment, all first bonding elements BE1 between the electronic elements EL and the first substrate SB1 may be broken through one breaking process of the first bonding elements BE1, such that all electronic elements EL on the first substrate SB1 are debonded from the first substrate SB1 in one-time, but not limited thereto. In other embodiments, multiple debonding steps may be performed to debond the electronic elements EL from the first substrate SB1 in batches. As shown in the process (II) of FIG. 2, after the debonding step of the electronic elements EL and the first substrate SB1, a portion P1 of the first bonding element BE1 may be remained on the electronic element EL, and a portion P2 of the first bonding element BE1 may be remained on the first substrate SB1. After the debonding step of the electronic elements EL and the first substrate SB1, the first substrate SB1 (and the portion P2 of the first bonding element BE1 remained on the first substrate SB1) may be scrapped.

After the electronic elements EL are separated from the first substrate SB1, the step S106 of the manufacturing method M100 may be performed to transfer the electronic elements EL to a temporary substrate TSB. The electronic elements EL may be transferred to the temporary substrate TSB by mass transfer technology (such as fluid transfer, pick and place transfer or other suitable ways). For example, the electronic elements EL of the present embodiment may be transferred to the temporary substrate TSB through fluid transfer, but not limited thereto. As shown in the process (III) of FIG. 2, after the electronic elements EL are separated from the first substrate SB1, the electronic elements EL may be transferred to the temporary substrate TSB through fluid FL, such that the electronic elements EL in the electronic panel EP can be recycled. The electronic elements EL may be placed on the temporary substrate TSB in the way that the portion P1 of the first bonding element BE1 faces upward, that is, the electronic element EL is located between the portion P1 of the first bonding element BE1 and the temporary substrate TSB. In other embodiments, the electronic elements EL may be transferred to the temporary substrate TSB through other suitable ways (such as pick and place transfer). In the following, the electronic elements EL transferred to the temporary substrate TSB may be called “recycled electronic elements”.

In the present embodiment, as shown in the process (III) of FIG. 2, the temporary substrate TSB may include magnetic elements ME, wherein the magnetic elements ME may be used to define the predetermined disposition positions of the electronic elements EL. Specifically, the electronic elements EL of the present embodiment may include a ferromagnetic material, and the temporary substrate TSB may include a plurality of magnetic elements ME respectively used for attracting the electronic elements EL. Therefore, the electronic elements EL may be fixed on the temporary substrate TSB through the magnetic elements ME. For example, in the manufacturing process of the electronic elements EL, the electronic element EL may be made ferromagnetic by additionally disposing a ferromagnetic material layer in the electronic element EL. The ferromagnetic material layer mentioned above may for example be disposed at a side of the electronic element EL opposite to the electrode of the electronic element EL, but not limited thereto. It should be noted that the process (III) of FIG. 2 just exemplarily shows the structure that the temporary substrate TSB includes the magnetic elements ME, and the disposition positions of the magnetic elements ME is not limited to what is shown in the process (III) of FIG. 2. In some embodiments, the magnetic elements ME may be disposed at a side of the temporary substrate TSB opposite to the predetermined disposition positions of the electronic elements EL and may correspond to the predetermined disposition positions of the electronic elements EL. In some embodiments, the magnetic elements ME may be included in the temporary substrate TSB, or the magnetic elements ME may be embedded in the temporary substrate TSB.

After the electronic elements EL are transferred to the temporary substrate TSB, the manufacturing method M100 may further include removing portions of the first bonding elements BE1 remained on the electronic elements EL. For example, as shown in the process (IV) of FIG. 3, after the electronic elements EL are disposed on the temporary substrate TSB in the way that the portions P1 of the first bonding elements BE1 face upward, the portions P1 of the first bonding elements BE1 remained on the electronic elements EL may be removed, but not limited thereto. In some embodiments, after the electronic elements EL are transferred to the temporary substrate TSB, the portions P1 of the first bonding elements BE1 remained on the electronic elements EL may not be removed.

After the electronic elements EL are transferred to the temporary substrate TSB, the manufacturing method M100 of the electronic device ED may further include forming second bonding elements BE2 respectively on the electronic elements EL. The second bonding element BE2 may for example include suitable conductive glue and may be disposed on the electronic element EL in any suitable way. For example, as shown in the process (IV) of FIG. 3, conductive glue may be disposed on the electronic elements EL through a dispensing tool TL as the second bonding elements BE2 in the present embodiment, but not limited thereto. The second bonding elements BE2 may be disposed corresponding to the positions where the electronic elements EL are bonded on the substrate of an electronic device ED (that is, the second substrate SB2 mentioned in the following) in subsequent process. For example, the second bonding elements BE2 may be disposed corresponding to the original positions of the first bonding elements BE1. The electronic elements EL may be bonded on the substrate (that is, the second substrate SB2 mentioned in the following) of the electronic device ED provided in subsequent process through the second bonding elements BE2. In the present embodiment, since the manufacturing method M100 may include the step of removing the first bonding elements BE1 remained on the electronic elements EL mentioned above, the second bonding elements BE2 may be directly disposed on the electronic elements EL, but not limited thereto. In some embodiments, the manufacturing method M100 may not include the step of removing the first bonding elements BE1 remained on the electronic elements EL mentioned above. In such condition, the second bonding elements BE2 may be disposed on the portions P1 of the first bonding elements BE1, that is, the portion P1 of the first bonding element BE1 may be disposed between the second bonding element BE2 and the electronic element EL.

After the second bonding elements BE2 are disposed on the electronic elements EL, the step S108 may be performed to transfer the electronic elements EL from the temporary substrate TSB to a second substrate SB2, and the step S110 may be performed to bond the electronic elements EL on the second substrate SB2. Specifically, the electronic elements EL on the temporary substrate TSB may be transferred to the second substrate SB2 by mass transfer technology, and the electronic elements EL may be bonded on the second substrate SB2 through the second bonding elements BE2 to form the electronic device ED. The structural feature of the second substrate SB2 may refer to the structure of the first substrate SB1 mentioned above. For example, the second substrate SB2 may include a base BS2 and a circuit layer CL2 disposed on the base BS2, but not limited thereto. In the present embodiment, the electronic elements EL (or the recycled electronic elements) transferred from the temporary substrate TSB may serve as the repairing electronic elements in the electronic device ED, but not limited thereto. In such condition, as shown in the process (V)-1 and the process (V)-2 of FIG. 3, the manufacturing process of the electronic device ED may include disposing non-recycled electronic elements NEL on the second substrate SB2 at first, and then an inspection step of the electronic elements may be performed to confirm the defective non-recycled electronic elements NEL, and then the defective non-recycled electronic elements NEL may be removed. After that, the electronic elements EL transferred from the temporary substrate TSB may serve as the repairing electronic elements and be bonded on the second substrate SB2, thereby forming the electronic device ED. The non-recycled electronic elements NEL may be bonded on the second substrate SB2 through bonding elements BE. The material of the bonding element BE may refer to the material of the first bonding element BE1 and the material of the second bonding element BE2 mentioned above, but not limited thereto. In some embodiments, the electronic elements in the electronic device ED may use the electronic elements EL transferred from the temporary substrate TSB, that is, the electronic elements in the electronic device ED may include the electronic elements EL transferred from the temporary substrate TSB (or the recycled electronic elements).

The detailed structures of the electronic element EL and the first substrate SB1 bonded by different bonding methods in the present disclosure in the step of recycling the electronic elements EL and the step of bonding the recycled electronic elements EL on the second substrate SB2 will be described in the following.

Referring to FIG. 4, FIG. 4 schematically illustrates bonding ways of an electronic element according to the first embodiment of the present disclosure. Specifically, FIG. 4 shows several examples of the structures of the electronic element EL and the first substrate SB1 bonded by eutectic bonding (such as Cu—Cu bonding) in the process shown in the manufacturing method M100. As shown in the structure (a) of FIG. 4, in the present embodiment, the electronic element EL may be bonded on the first substrate SB1 through eutectic bonding. In such condition, the electrode E1 may be disposed on the electronic element EL, and the electronic element EL may contact the bonding pad BP1 on the first substrate SB1 through the electrode E1, such that the electronic element EL can be bonded on the first substrate SB1. The electrode E1 and the bonding pad BP1 may include suitable conductive materials such as copper (Cu), but not limited thereto. The electrode E1 and the bonding pad BP1 may form the first bonding element BE1 mentioned above. In such condition, the electrode E1 may have a height H1, the bonding pad BP1 may have a height H2, and the height HB of the first bonding element BE1 may be the sum of the height H1 and the height H2.

In some embodiments, as shown in the structure (b) of FIG. 4, after the electronic elements EL are debonded from the first substrate SB1, the portions (that is, the portions P1 mentioned above) of the first bonding elements BE1 remained on the electronic elements EL may further be removed, that is, only the electronic elements EL remain. In such condition, as shown in the structure (c) to the structure (e) shown in FIG. 4, after the electronic elements EL in which the second bonding elements BE2 are disposed are transferred from the temporary substrate TSB to the second substrate SB2, the second bonding elements BE2 may contact the bonding pads BP2 on the second substrate SB2, thereby bonding the electronic elements EL on the second substrate SB2. The second bonding element BE2 of the present embodiment may for example be an electrode or the same conductive material layer as the electrode E1, but not limited thereto. The second bonding element BE2 and the bonding pad BP2 may form a bonding element BM, and the electronic element EL can be bonded on the second substrate SB2 through the bonding element BM. The bonding element BM may have a height HB′, wherein the height HB′ of the bonding element BM may be the sum of the height H1′ of the second bonding element BE2 and the height H2′ of the bonding pad BP2. In addition, in the present embodiment, the height H2′ of the bonding pad BP2 may for example be the same as the height (that is, the height H2) of the bonding pad BP1, that is, the bonding pads on different substrates may for example have the same height, but not limited thereto. In such condition, the height HB′ of the bonding element BM may change with the change of the height H1′ of the second bonding element BE2. The height H1′ of the second bonding element BE2 may for example be affected by the process parameters (such as the amount of conductive glue applied) of the second bonding element BE2. In detail, in an embodiment, as shown in the structure (c) of FIG. 4, the height H1′ of the second bonding element BE2 may be the same as the height H1 of the previously formed electrode E1. In such condition, the height HB′ of the bonding element BM may be the sum of the height H1′ and the height H2′ and may be the same as the height HB of the first bonding element BE1. In an embodiment, as shown in the structure (d) of FIG. 4, the height H1′ of the second bonding element BE2 may be less than the height H1 of the previously formed electrode E1. In such condition, the height HB′ of the bonding element BM may be the sum of the height H1′ and the height H2′ and may be less than the height HB of the first bonding element BE1. In an embodiment, as shown in the structure (e) of FIG. 4, the height H1′ of the second bonding element BE2 may be greater than the height H1 of the previously formed electrode E1. In such condition, the height HB′ of the bonding element BM may be the sum of the height H1′ and the height H2′ and may be greater than the height HB of the first bonding element BE1.

In some embodiments, after the electronic elements EL are debonded from the first substrate SB1, the portions (that is, the portions P1) of the first bonding elements BE1 remained on the electronic elements EL may not be removed. For example, as shown in the structure (f) of FIG. 4, after the electronic elements EL are debonded from the first substrate SB1, the portions P1 of the first bonding elements BE1 may be remained, but not limited thereto. The portion P1 for example includes cocrystal of the electrode E1 and the bonding pad BP1, but not limited thereto. In such condition, as shown in the structure (g) of FIG. 4, the second bonding element BE2 may be disposed corresponding to the portion P1 of the first bonding element BE1, and after the electronic element EL is bonded on the second substrate SB2, the second bonding element BE2 may contact the bonding pad BP2 on the second substrate SB2. That is, the bonding pad BP2, the second bonding element BE2 and the portion P1 of the first bonding element BE1 may be disposed in sequence from a side of the second substrate SB2 to a side of the electronic element EL. The bonding pad BP2, the second bonding element BE2 and the portion P1 of the first bonding element BE1 may form the bonding element BM mentioned above. Therefore, the height HB′ of the bonding element BM may be the sum of the height H3 of the portion P1, the height H2′ and the height H1′ of the second bonding element BE2 and may be greater than the height HB of the first bonding element BE1. In some embodiments, as shown in the structure (h) of FIG. 4, the electronic element EL may be bonded on the second substrate SB2 by the portion P1 of the first bonding element BE1 directly contacting the bonding pad BP2 on the second substrate SB2. The bonding pad BP2 and the portion P1 may form the bonding element BM mentioned above. Therefore, the height HB′ of the bonding element BM may be the sum of the height H3 and the height H2′. In such condition, the height HB′ of the bonding element BM may change with the change of the height H3 of the portion P1 of the first bonding element BE1 and may be greater than, less than, or equal to the height HB of the first bonding element BE1. It should be noted that the electrode E1 shown in the structure (f) of FIG. 4 may be removed (that is, the remained portion of the first bonding element BE1 may be removed) to get the structure shown in the structure (b) of FIG. 4.

Referring to FIG. 5, FIG. 5 schematically illustrates bonding ways of an electronic element according to a variant embodiment of the first embodiment of the present disclosure. Specifically, FIG. 5 shows several examples of the structures of the electronic element EL and the first substrate SB1 bonded by laser bonding in subsequent process. As shown in the structure (a) of FIG. 5, the electronic elements EL of the present embodiment may be bonded on the first substrate SB1 through laser bonding. In such condition, the electrode E1 may be disposed on the electronic element EL, wherein the electrode E1 may be electrically connected to the bonding pad BP1 on the first substrate SB1 through the solder ball SD, such that the electronic element EL can be bonded on the first substrate SB1. The electrode E1, the solder ball SD and the bonding pad BP1 may include suitable conductive materials. The electrode E1, the solder ball SD and the bonding pad BP1 may form the first bonding element BE1 mentioned above. In such condition, the electrode E1 may have a height H1, the bonding pad BP1 may have a height H2, the solder ball SD may have a height H3, and the height HB of the first bonding element BE1 may be the sum of the height H1, the height H2, and the height H3.

In some embodiments, as shown in the structure (b) of FIG. 5, after the electronic elements EL are debonded from the first substrate SB1, the portions (that is, the above-mentioned portions P1) of the first bonding elements BE1 remained on the electronic elements EL may further be removed, that is, only the electronic elements EL remain. In such condition, when the second bonding element BE2 is disposed on the electronic element EL, the second bonding element BE2 may include the electrode E1′ and/or the solder ball SD′. In detail, in an embodiment, as shown in the structure (c) of FIG. 5, the second bonding element BE2 may include the electrode E1′ and the solder ball SD′. The electrode E1′ and the solder ball SD′ may for example include the same materials as the electrode E1 and the solder ball SD respectively, but not limited thereto. In such condition, the bonding element BM may be formed of the electrode E1′, the solder ball SD′ and the bonding pad BP2. In the structure (c), the electrode E1′ may have a height H1′, wherein the height H1′ may for example be the same as the height H1 of the electrode E1; the solder ball SD′ may have a height H3′, wherein the height H3′ may for example be the same as the height H3 of the solder ball SD; the bonding pad BP2 may have a height H2′, wherein the height H2′ may be the same as the height H2 of the bonding pad BP1. Therefore, the height HB′ of the bonding element BM may be the sum of the height H1′, the height H2′ and the height H3′ and may be the same as the height HB of the first bonding element BE1. It should be noted that in some embodiments, in the structure (c), the height H1′ of the electrode E1′ may not be the same as the height H1, and/or the height H3′ of the solder ball SD′ may not be the same as the height H3, and the height HB′ of the bonding element BM may be different from the height HB of the first bonding element BE1. In an embodiment, as shown in the structure (d) of FIG. 5, the second bonding element BE2 may include the electrode E1′ but not include the solder ball SD′, that is, the electronic element EL is bonded on the second substrate SB2 through the electrode E1′ and the bonding pad BP2. In the present embodiment, in the structure (d), the height H1′ of the electrode E1′ may for example be the same as the height H1 of the electrode E1, and the height H2′ of the bonding pad BP2 may for example be the same as the height H2 of the bonding pad BP1. Therefore, the height HB′ of the bonding element BM may be the sum of the height H1 and the height H2 and may be less than the height HB of the first bonding element BE1. It should be noted that in some embodiments, in the structure (d), the height H1′ of the electrode E1′ may not be the same as the height H1.

In some embodiments, as shown in the structure (e) of FIG. 5, after the electronic elements EL are debonded from the first substrate SB1, breakage of the first bonding elements BE1 may occur at the electrodes E1. Therefore, the portion P1 of the first bonding element BE1 remained on the electronic element EL may be a portion of the electrode E1. In addition, in the present embodiment, the portion P1 of the first bonding element BE1 remained on the electronic element EL may not be removed. In such condition, in an embodiment, as shown in the structure (d) of FIG. 5, the second bonding element BE2 may not be disposed on the electronic element EL, and the electronic element EL may be bonded on the second substrate SB2 by making the portion of the electrode E1 remained on the electronic element EL contact the bonding pad BP2. In such condition, the electrode E1′ shown in the structure (d) may be the portion of the electrode E1 remained on the electronic element EL in the present embodiment, and the bonding element BM may be formed of the electrode E1′ and the bonding pad BP2. Therefore, the height H1′ of the electrode E1′ may be less than the height H1 of the electrode E1, the height H2′ of the bonding pad BP2 may be the same as the height H2 of the bonding pad BP1, and the height HB′ of the bonding element BM may be the sum of the height H1′ and the height H2′ and may be less than the height HB of the first bonding element BE1. In an embodiment, as shown in the structure (f) of FIG. 5, the second bonding element BE2 may be disposed on the portion of the electrode E1 remained on the electronic element EL, and the electronic element EL may be bonded on the second substrate SB2 by making the second bonding element BE2 contact the bonding pad BP2. The second bonding element BE2 may for example include the solder ball SD′ mentioned above, but not limited thereto. That is, the bonding element BM may be formed of the bonding pad BP2, the solder ball SD′ and the electrode E1′ disposed in sequence, wherein the electrode E1′ may be a portion of the electrode E1 remained on the electronic element EL in the present embodiment. Therefore, the height H1′ of the electrode E1′ may be less than the height H1 of the electrode E1. The height H3′ of the solder ball SD′ may for example be the same as the height H3 of the solder ball SD. The height H2′ of the bonding pad BP2 may be the same as the height H2 of the bonding pad BP1. In such condition, the height HB′ of the bonding element BM may be the sum of the height H1′, the height H2′ and the height H3′ and may be less than the height HB of the first bonding element BE1.

In some embodiments, as shown in the structure (g) of FIG. 5, after the electronic elements EL are debonded from the first substrate SB1, breakage of the first bonding elements BE1 may occur at the solder balls SD. Therefore, the portion P1 of the first bonding element BE1 remained on the electronic element EL may include the electrode E1 and a portion of the solder ball SD. In addition, the portion P1 of the first bonding element BE1 remained on the electronic element EL may not be removed in the present embodiment. In such condition, in an embodiment, as shown in the structure (h) of FIG. 5, the second bonding element BE2 may be disposed on the portion of the solder SD remained on the electronic element EL, and the electronic element EL may be bonded on the second substrate SB2 by making the second bonding element BE2 contact the bonding pad BP2. The second bonding element BE2 may for example include the solder ball SD″, but not limited thereto. That is, the bonding element BM may be formed of the bonding pad BP2, the solder ball SD″, the solder ball SD′ and the electrode E1 disposed in sequence, wherein the solder ball SD′ may be the portion of the solder SD remained on the electronic element EL in the present embodiment. Therefore, the height H3′ of the solder ball SD′ is less than the height H3 of the solder ball SD. The height H2′ of the bonding pad BP2 may be the same as the height H2 of the bonding pad BP1. The solder ball SD″ may have a height H4. In such condition, the height HB′ of the bonding element BM may be the sum of the height H1, the height H2′, the height H3′ and the height H4, and the height HB′ of the bonding element BM may be greater than or equal to the height HB of the first bonding element BE1, depending on the value of the height H4. It should be noted that in some embodiments, the second bonding element BE2 (such as the solder ball SD′ ‘) may not be disposed on the structure shown in the structure (g), and the electronic element EL may be bonded on the second substrate SB2 by making the solder ball SD’ contact the bonding pad BP2. In some embodiments, the remained portion (that is, the portion P1) of the first bonding element BE1 shown in the structure (g) may be completely removed to get the structure shown in the structure (b), or the remained portion of the first bonding element BE1 shown in the structure (g) may be partially removed to get the structure shown in the structure (e).

In some embodiments, as shown in the structure (i) of FIG. 5, after the electronic elements EL are debonded from the first substrate SB1, breakage of the first bonding elements BE1 may occur at the bonding pads BP1. Therefore, the portion P1 of the first bonding element BE1 remained on the electronic element EL may include the electrode E1, the solder ball SD and a portion of the bonding pad BP1. In addition, the portion P1 of the first bonding element BE1 remained on the electronic element EL may not be removed in the present embodiment. In such condition, in an embodiment, as shown in the structure (j) of FIG. 5, the second bonding element BE2 may be disposed on the portion of the bonding pad BP1 remained on the electronic element EL, and the electronic element EL may be bonded on the second substrate SB2 by making the second bonding element BE2 contact the bonding pad BP2. The second bonding element BE2 may for example include the solder ball SD′, but not limited thereto. That is, the bonding element BM may be formed of the bonding pad BP2, the solder ball SD′, the bonding pad BP1′, the solder ball SD and the electrode E1 disposed in sequence, wherein the bonding pad BP1′ may be the portion of the bonding pad BP1 remained on the electronic element EL in the present embodiment. Therefore, the height H5 of the bonding pad BP1′ is less than the height H2 of the bonding pad BP1. The height H2′ of the bonding pad BP2 may be the same as the height H2 of the bonding pad BP1. The solder ball SD′ may have a height H4. In such condition, the height HB′ of the bonding element BM may be the sum of the height H1, the height H3, the height H5, the height H4 and the height H2′, and the height HB′ of the bonding element BM may be greater than the height HB of the first bonding element BE1. In an embodiment, the second bonding element BE2 may not be disposed on the electronic element EL, and the electronic element EL may be bonded on the second substrate SB2 by making the portion of the bonding pad BP1 remained on the electronic element EL contact the bonding pad BP2. It should be noted that in some embodiments, the remained portion (that is, the portion P1) of the first bonding element BE1 shown in the structure (i) may be completely removed or partially removed to get the structure shown in the structure (b), the structure (e) or the structure (g).

According to the present disclosure, the electronic device ED may include at least one electronic element EL recycled from the electronic panel EP through the above-mentioned process, wherein when the electronic element EL is bonded on the second substrate SB2, the height of the electronic element EL may be affected by the manufacturing process of the second bonding element BE2 (such as the amount of conductive glue applied) and/or whether the portion P1 of the first bonding element BE1 remained on the electronic element EL is removed. The height of the electronic element EL described herein may be defined as the distance from a top surface of the electronic element EL to a top surface of the second substrate SB2 in the top view direction of the electronic device ED. In such condition, the electronic elements (for example, including the electronic element EL and/or the non-recycled electronic element NEL) in the electronic device ED may have height difference. In other words, in the cross-sectional view of the electronic device ED, it can be observed that the top surfaces of the electronic elements have ups and downs.

Back to FIG. 3, as shown in the process (V)-1 and the process (V)-2 of FIG. 3, the electronic element EL of the present embodiment may serve as the repairing electronic element in the electronic device ED. Therefore, after the electronic elements EL are bonded on the second substrate SB2, the electronic device ED may include a first electronic element EL1 and a second electronic element EL2, wherein one of the first electronic element EL1 and the second electronic element EL2 is the non-recycled electronic element NEL, and another one of the first electronic element EL1 and the second electronic element EL2 is the recycled electronic element (that is, the electronic element EL, which will not be redundantly described in the following). For example, the first electronic element EL1 may be the non-recycled electronic element NEL, and the second electronic element EL2 may be the recycled electronic element, but not limited thereto. The first electronic element EL1 may have a height Ha, and the second electronic element EL2 may have a height Hb. The height Ha of the first electronic element EL1 may be defined as the maximum distance between the top surface S2 of the first electronic element EL1 and the top surface S3 of the second substrate SB2 in the top view direction of the electronic device ED. The height Hb of the second electronic element EL2 may be defined as the maximum distance between the top surface S4 of the second electronic element EL2 and the top surface S3 of the second substrate SB2 in the top view direction of the electronic device ED. “The top surface S3 of the second substrate SB2” described herein may for example be the top surface of the layer in the circuit layer CL2 that is farthest from the base BS2, but not limited thereto. In some embodiments, as shown in the process (V)-1 of FIG. 3, the height Ha of the first electronic element EL1 may be greater than the height Hb of the second electronic element EL2, that is, the height of the non-recycled electronic element NEL may be greater than the height of the recycled electronic element. In such condition, the height Ha and the height Hb may satisfy the following equation (1):

$$0.05 \leq ( Ha - Hb ) / Ha \leq 1.1 \qquad ( 1 )$$

Or, in some embodiments, the height Hb of the second electronic element EL2 may be greater than the height Ha of the first electronic element EL1, that is, the height of the recycled electronic element may be greater than the height of the non-recycled electronic element NEL. In such condition, the height Ha and the height Hb may satisfy the following equation (2):

$$0.05 \leq ( Hb - Ha ) / Hb \leq 1.1 \qquad ( 2 )$$

Specifically, in the present embodiment, a ratio of the difference in height of a recycled electronic element and a non-recycled electronic element NEL to the height of one of the two electronic elements with a greater height may range from 0.05 to 1.1 (that is, 0.05≤(Ha−Hb)/Ha or (Hb−Ha)/Hb≤1.1), but not limited thereto. In some embodiments, the above-mentioned ratio may range from 0.1 to 1 (that is, 0.1≤(Ha−Hb)/Ha or (Hb−Ha)/Hb≤1). In some embodiments, the above-mentioned ratio may range from 0.15 to 0.95 (that is, 0.15≤(Ha−Hb)/Ha or (Hb−Ha)/Hb≤0.95).

According to the present embodiment, when the first bonding element BE1 and/or the second bonding element BE2 are bonded on the second substrate SB2 by eutectic bonding (for example, Cu—Cu bonding), a ratio of the difference in height of a recycled electronic element and a non-recycled electronic element NEL to the height of one of the two electronic elements with a greater height may range from 0.1 to 1.1 (that is, 0.1≤(Ha−Hb)/Ha or (Hb−Ha)/Hb≤1.1), but not limited thereto. In some embodiments, the above-mentioned ratio may range from 0.15 to 1 (that is, 0.15≤(Ha−Hb)/Ha or (Hb−Ha)/Hb≤1). In some embodiments, the above-mentioned ratio may range from 0.2 to 0.95 (that is, 0.2≤(Ha−Hb)/Ha or (Hb−Ha)/Hb≤0.95).

According to the present embodiment, when the first bonding element BE1 and/or the second bonding element BE2 are bonded on the second substrate SB2 by laser bonding, a ratio of the difference in height of a recycled electronic element and a non-recycled electronic element NEL to the height of one of the two electronic elements with a greater height may range from 0.05 to 0.55 (that is, 0.05≤(Ha−Hb)/Ha or (Hb−Ha)/Hb≤0.55), but not limited thereto. In some embodiments, the above-mentioned ratio may range from 0.1 to 0.5 (that is, 0.1≤(Ha−Hb)/Ha or (Hb−Ha)/Hb≤0.5). In some embodiments, the above-mentioned ratio may range 0.15 to 0.45 (that is, 0.15≤(Ha−Hb)/Ha or (Hb−Ha)/Hb≤0.45).

In addition, in the present embodiment, the height difference between two non-recycled electronic elements NEL may be less than the height difference between a non-recycled electronic element NEL and a recycled electronic element. In detail, as shown in the process (V)-1 of FIG. 3, the electronic device ED may further include a third electronic element EL3, wherein the third electronic element EL3 may be the non-recycled electronic element NEL. That is, the first electronic element EL1 and the third electronic element EL3 are non-recycled electronic elements NEL, and the second electronic element EL2 is the recycled electronic element. The third electronic element EL3 may have a height Hc, wherein the height Hc may be defined as the maximum distance between the top surface S5 of the third electronic element EL3 and the top surface S3 of the second substrate SB2 in the top view direction of the electronic device ED. According to the present embodiment, the difference between the height Hc and the height Ha may be less than the difference between the height Hc and the height Hb (that is, |Hc−Ha|<|Hc−Hb|). For example, a ratio of the difference in height of two non-recycled electronic elements NEL to the height of one of the two non-recycled electronic elements NEL with a greater height may be less than 0.05, but not limited thereto.

It should be noted that in some embodiments, the electronic device ED may use recycled electronic elements (that is, the electronic elements EL) as its electronic elements, that is, the electronic elements in the electronic device ED may all be the electronic elements EL. In such condition, “the first electronic element EL1” and “the second electronic element EL2” mentioned above may all be the recycled electronic elements, and the equations mentioned above may be used to represent the height relationship between two recycled electronic elements.

According to the present embodiment, after the electronic elements EL are bonded on the first substrate SB1 to form the electronic panel EP, if it is detected that the first substrate SB1 is a defective product, the electronic elements EL can be recycled according to the above-mentioned method, and the recycled electronic elements EL may be disposed in the electronic device ED as the electronic elements or the repairing electronic elements of the electronic device ED. Therefore, the situation that the electronic elements EL are scrapped with the first substrate SB1 may be reduced, thereby reducing the production cost of the electronic device or reducing carbon emissions. In addition, as mentioned above, after the recycled electronic elements are disposed in the electronic device ED, the recycled electronic elements in the electronic device ED may be confirmed through the height difference of the electronic elements. It should be noted that in some embodiments, the recycled electronic elements in electronic device ED may also be confirmed through interface analysis in addition to height difference. Specifically, after the electronic element EL is separated from the first substrate SB1, the second bonding element BE2 is disposed on the electronic element EL, and the electronic element EL is bonded on the second substrate SB2 through the second bonding element BE2, the interface properties between the electronic element EL and the bonding element (that is, the above-mentioned bonding element BM) disposed between the electronic element EL and the second substrate SB2 may change. Therefore, the recycled electronic elements can be confirmed by performing interface analysis on the interface between the electronic element EL and the bonding element BM. The interface analysis mentioned above may for example include metallographic analysis, grain boundary analysis or other suitable analysis methods. Metallographic analysis may be performed through a metallographic microscope to confirm the elemental composition or physical properties of the materials on both sides of the bonding surface. Grain boundary analysis may be performed by electron back scatter diffraction (EBSD) to confirm the crystal phase of the materials on both sides of the bonding surface or the electron migration efficiency at the bonding surface.

Other embodiments of the present disclosure will be described in the following. In order to simplify the description, the same elements or layers in the following embodiments would be labeled with the same symbol, and the features thereof will not be redundantly described. The differences between the embodiments will be detailed in the present disclosure. It should be noted that the features described in the embodiments can be applied to each other, and a feature is not limited to the structure of the embodiment in which the feature is shown.

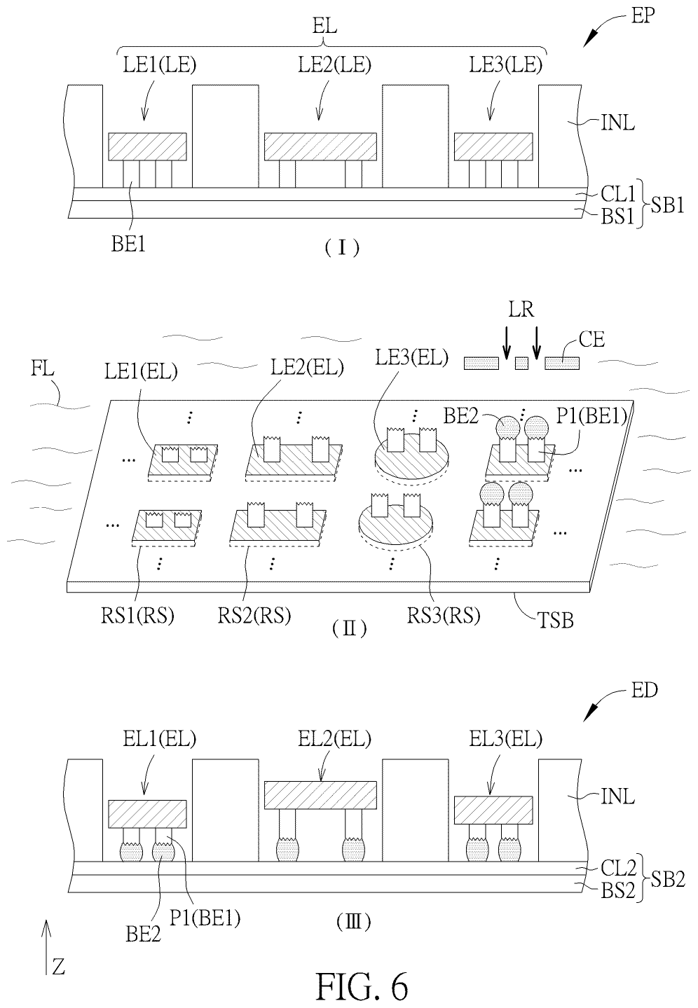

Referring to FIG. 6, FIG. 6 schematically illustrates a manufacturing process of an electronic device according to a second embodiment of the present disclosure. In the present embodiment, the electronic elements EL in the electronic panel EP may include the light emitting elements LE of the same color and different appearances. For example, in the process (I) of FIG. 6, the first light emitting element LE1, the second light emitting element LE2 and the third light emitting element LE3 of the electronic panel EP may emit lights of the same color but have different appearances. In detail, as shown in the process (II) of FIG. 6, the first light emitting element LE1 and the second light emitting element LE2 may have different sizes. For example, the first light emitting element LE1 and the second light emitting element LE2 may have different areas in the top view direction (or the projected area of the first light emitting element LE1 and the projected area of the second light emitting element LE2 on the first substrate SB1 are different). In addition, the first light emitting element LE1 and the third light emitting element LE3 may have different shapes. For example, the first light emitting element LE1 and the third light emitting element LE3 have different shapes in the top view direction. It should be noted that the electronic panel EP may include multiple groups of first light emitting elements LE1, second light emitting elements LE2 and third light emitting elements LE3, which is not limited to what is shown in the process (I) of FIG. 6. The features of other elements or layers of the electronic panel EP may refer to the contents mentioned above, and will not be redundantly described.

The manufacturing method of the electronic device ED of the present embodiment may refer to the manufacturing method M100 mentioned above. First, the first bonding elements BE1 between the electronic elements EL and the first substrate SB1 may be broken, thereby debonding the electronic elements EL from the first substrate SB1. The breaking method of the first bonding element BE1 may refer to the contents mentioned above, and will not be redundantly described. After that, the electronic elements EL may be transferred to the temporary substrate TSB by fluid transfer. For example, as shown in the process (II) of FIG. 6, the electronic elements EL may be transferred to the temporary substrate TSB through the fluid FL. According to the present embodiment, as shown in the process (II) of FIG. 6, the temporary substrate TSB may include a plurality of recesses RS respectively used for accommodating the electronic elements EL. The sizes of the recesses RS may be determined according to the sizes of the electronic elements EL, such that the electronic elements EL can fall into the recesses RS. Specifically, in the present embodiment, the electronic elements EL may have at least two sizes, and the recesses RS of the temporary substrate TSB may have at least two sizes which are respectively used for accommodating the electronic elements having the two sizes. For example, as shown in the process (II) of FIG. 6, the temporary substrate TSB may include the recesses RS1, the recesses RS2 and the recesses RS3, wherein the recesses RS1, the recesses RS2 and the recesses RS3 may have different sizes and may be used for accommodating the first light emitting elements LE1, the second light emitting elements LE2 and the third light emitting elements LE3 respectively. In such condition, the recess RS1, the recess RS2 and the recess RS3 may have shapes and sizes matching the first light emitting element LE1, the second light emitting element LE2 and the third light emitting element LE3 respectively. Therefore, the disposition positions of the light emitting elements LE with different appearances may be defined on the temporary substrate TSB. It should be noted that the electronic elements EL of the present embodiment may be disposed on the temporary substrate TSB through the above-mentioned magnetic elements ME, which is not limited to the method mentioned above. Similarly, in the embodiment shown in FIG. 2, the electronic elements EL may be disposed on the temporary substrate TSB through the recesses RS.

After the electronic elements EL are transferred to the temporary substrate TSB, the second bonding elements BE2 may be disposed on the electronic elements EL. In the present embodiment, the second bonding elements BE2 may for example be disposed by laser dispensing. In detail, as shown in the process (II) of FIG. 6, a conductive element CE may be placed at a side of the electronic element EL where the second bonding element BE2 is to be disposed, wherein the conductive element CE includes the material of the second bonding element BE2. After that, a laser LR may be applied to the portion of the conductive element CE that corresponds to the predetermined disposition position of the second bonding element BE2 on the electronic element EL, such that the portion of the conductive element CE can be transferred to the predetermined disposition position of the second bonding element BE2 on the electronic element EL, thereby completing the disposition of the second bonding element BE2. It should be noted that the second bonding element BE2 of the present embodiment may also be disposed in the way mentioned in the above-mentioned first embodiment. Similarly, in the embodiment shown in FIG. 2, the second bonding element BE2 may be disposed by laser dispensing.

In the present embodiment, after the electronic elements EL are transferred to the temporary substrate TSB, the portions P1 of the first bonding elements BE1 remained on the electronic elements EL may not be removed, and therefore, the portions P1 of the first bonding elements BE1 may be located between the second bonding elements BE2 and the electronic elements EL after the second bonding elements BE2 are disposed. It should be noted that the portions P1 of the first bonding elements BE1 remained on the electronic elements EL may be removed before the disposition of the second bonding elements BE2, it is not limited in the present embodiment.

After the second bonding elements BE2 are disposed, the electronic elements EL may be transferred from the temporary substrate TSB to the second substrate SB2 and bonded on the second substrate SB2 to form the electronic device ED. In the present embodiment, the electronic elements in the electronic device ED may all be the recycled electronic elements (that is, the electronic elements EL). In such condition, as shown in the process (III) of FIG. 6, the height relationship between any two of the first electronic element EL1, the second electronic element EL2 and the third electronic element EL3 may refer to the equation (1) and the equation (2) mentioned above, and will not be redundantly described. It should be noted that the electronic elements EL of the present embodiment may also serve as the repairing electronic elements in the electronic device ED.

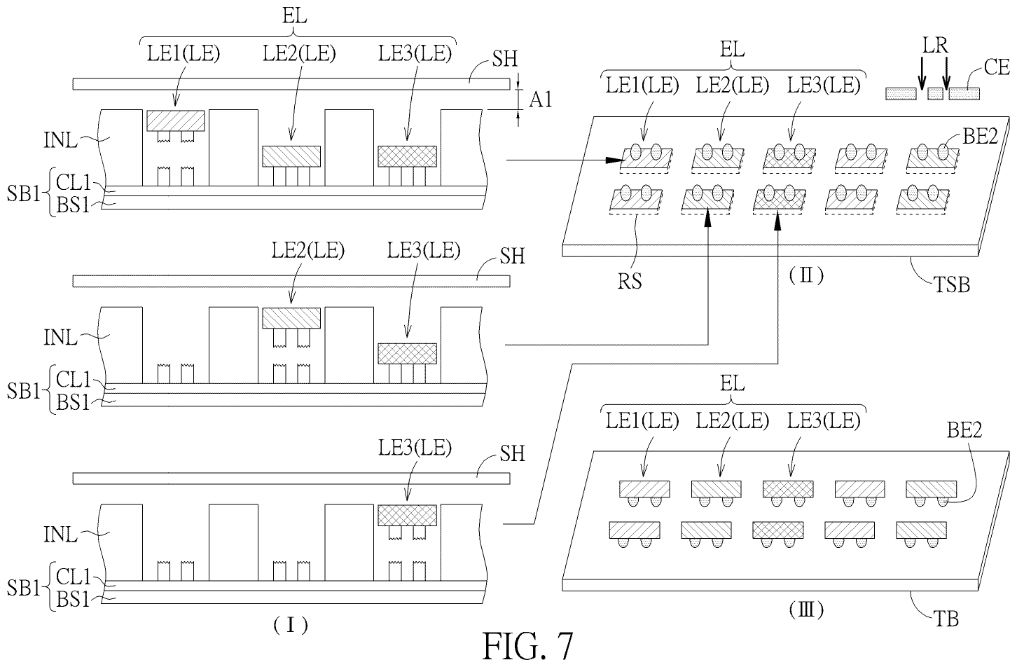

Referring to FIG. 7, FIG. 7 schematically illustrates a manufacturing process of an electronic device according to a third embodiment of the present disclosure. In the present embodiment, the electronic elements EL in the electronic panel EP may include the light emitting elements LE of different colors and the same appearance. Specifically, as shown in the process (I) of FIG. 7, the first light emitting elements LE1, the second light emitting elements LE2 and the third light emitting elements LE3 in the electronic panel EP may emit lights of different colors. For example, the first light emitting elements LE1, the second light emitting elements LE2 and the third light emitting elements LE3 may respectively emit red light, green light and blue light, which can be mixed into white light, but not limited thereto. In such condition, the first light emitting element LE1, the second light emitting element LE2 and the third light emitting element LE3 may respectively be included in a sub-pixel, and the sub-pixels may form a pixel. In addition, the first light emitting element LE1, the second light emitting element LE2 and the third light emitting element LE3 may have the same shape and the same size.

In the present embodiment, the electronic elements EL may be debonded from the first substrate SB1 through multiple debonding processes, but not limited thereto. As shown in the process (I) of FIG. 7, the first bonding elements BE1 between the first light emitting elements LE1 and the first substrate SB1 may be broken at first, such that the first light emitting elements LE1 may be separated from the first substrate SB1. After that, the first light emitting elements LE1 may be transferred to the temporary substrate TSB by pick and place transfer (for example, by mechanical clamping). After that, the second light emitting elements LE2 and the third light emitting elements LE3 may be separated from the first substrate SB1 in sequence through the above-mentioned way and may be transferred to the temporary substrate TSB. Therefore, the step of debonding the electronic elements EL from the first substrate SB1 and the step of transferring the electronic elements EL to the temporary substrate TSB may be completed. It should be noted that the first light emitting elements LE1, the second light emitting elements LE2 and the third light emitting elements LE3 may be separated from the first substrate SB1 in any order, which is not limited to the order mentioned above. In addition, as shown in the process (II) of FIG. 7, the temporary substrate TSB of the present embodiment may include the plurality of recesses RS for accommodating the first light emitting elements LE1, the second light emitting elements LE2 and the third light emitting elements LE3, but not limited thereto. It should be noted that the debonding method of the electronic elements EL and the structure of the temporary substrate TSB of the present embodiment may also refer to the content in the above-mentioned embodiments.

In the present embodiment, the manufacturing method M100 may further include disposing a baffle SH above the first substrate SB1 before the step of debonding the electronic elements EL from the first substrate SB1, such that the electronic elements EL may be located between the first substrate SB1 and the baffle SH. A distance A1 may be included between the baffle SH and the first substrate SB1, wherein the distance A1 may be less than 10 micrometers (μm) (that is, A1<10 μm), but not limited thereto. In some embodiments, the distance A1 may be less than 9 μm (that is, A1<9 μm). In some embodiments, the distance A1 may be less than 8 μm (that is, A1<8 μm). In some embodiments, when the first substrate SB1 does not include the insulating layer INL, the distance A1 may be defined as the minimum distance between the baffle SH and the top surface of the circuit layer CL1 in the top view direction. In some embodiments, when the first substrate SB1 includes the insulating layer INL, the distance A1 may be defined as the minimum distance between the baffle SH and the top surface of the insulating layer INL in the top view direction. Through the disposition of the baffle SH, the possibility that the electronic elements EL are separated from the first substrate SB1 and are damaged or lost after the first bonding elements BE1 are broken may be reduced, thereby improving the recycling effect of the electronic elements EL. The step of disposing the baffle SH that is described in the present embodiment may be applied to the embodiments and variant embodiments of the present disclosure.

After the electronic elements EL are transferred to the temporary substrate TSB, the second bonding elements BE2 may be disposed after removing the first bonding elements BE1 remained on the electronic elements EL. As shown in the process (II) of FIG. 7, the second bonding elements BE2 may be disposed by laser dispensing in the present embodiment, but not limited thereto. In some embodiments, the second bonding elements BE2 may be disposed through the method described in the first embodiment above. In addition, after the second bonding elements BE2 are disposed, the manufacturing method M100 may further include performing an inspection step on the electronic elements EL. For example, as shown in the process (III) of FIG. 7, after the second bonding elements BE2 are disposed, the electronic elements EL may be transferred to an inspecting board TB and bonded on the inspecting board TB, and then any suitable method may be used to detect whether the electronic elements EL are defective products. The inspecting method of the electronic elements EL mentioned above may for example include electroluminescence (EL) or photoluminescence (PL), but not limited thereto. The inspecting step of the electronic elements EL described in the present embodiment may be applied to the embodiments and variant embodiments of the present disclosure.

After the inspecting step of the electronic elements EL, the electronic elements EL may be transferred from the inspecting board TB to the second substrate SB2 to form the electronic device ED. The detailed structure of the electronic device ED may refer to the contents in any embodiment mentioned above, and will not be redundantly described.

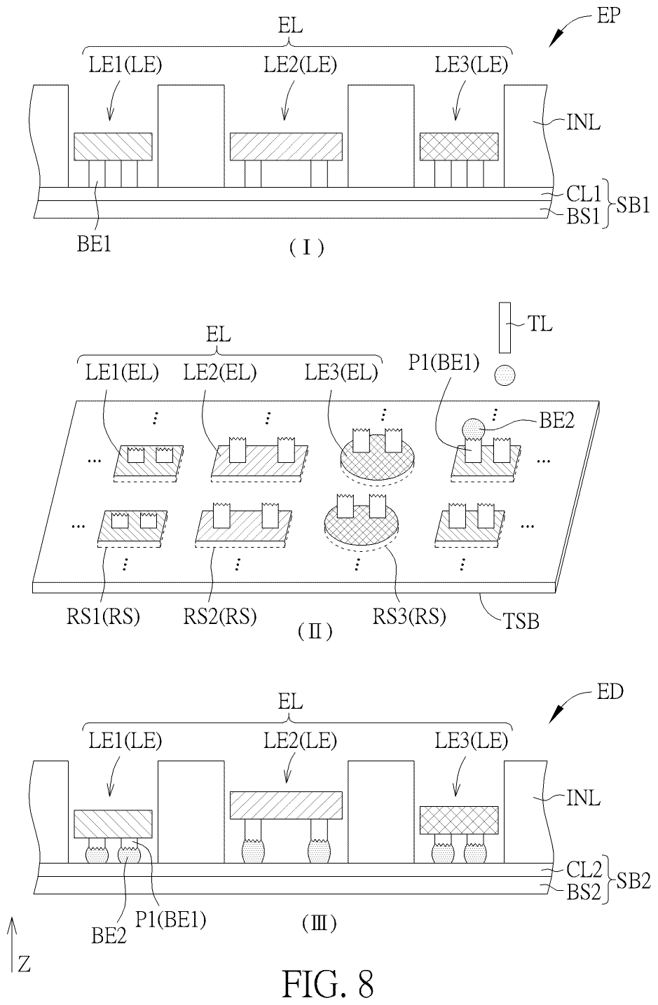

Referring to FIG. 8, FIG. 8 schematically illustrates a manufacturing process of an electronic device according to a fourth embodiment of the present disclosure. In the present embodiment, the electronic elements EL in the electronic panel EP may include the light emitting elements LE of different colors and different appearances. For example, the first light emitting elements LE1, the second light emitting elements LE2 and the third light emitting elements LE3 in the electronic panel EP may respectively emit red light, green light and blue light, which can be mixed into white light, but not limited thereto. In addition, the first light emitting element LE1 and the second light emitting element LE2 may have different areas in the top view direction, and the first light emitting element LE1 and the third light emitting element LE3 may have different shapes in the top view direction, but not limited thereto.

According to the present embodiment, the first bonding elements BE1 between all the electronic elements EL and the first substrate SB1 may be broken through one breaking step of the first bonding element BE1, thereby separating the first light emitting elements LE1, the second light emitting elements LE2 and the third light emitting elements LE3 from the first substrate SB1. The breaking method of the first bonding element BE1 may refer to the contents in the embodiments above. After that, the light emitting elements LE may be transferred to the temporary substrate TSB by pick and place transfer. The temporary substrate TSB may include the recesses RS1, the recesses RS2 and the recesses RS3 for accommodating the first light emitting elements LE1, the second light emitting elements LE2 and the third light emitting elements LE3 respectively. The features of the recess RS1, the recess RS2 and the recess RS3 may refer to the contents above, and will not be redundantly described. After that, the second bonding elements BE2 may be disposed on the electronic elements EL through the dispensing tool TL, and the electronic elements EL may be transferred to the second substrate SB2 to form the electronic device ED. In the present embodiment, the portions P1 of the first bonding elements BE1 remained on the electronic elements EL may not be removed. Therefore, after the second bonding elements BE2 are disposed, the portions P1 of the first bonding elements BE1 may be located between the second bonding elements BE2 and the electronic elements EL, but not limited thereto. In the present embodiment, the electronic elements in the electronic device ED may all be the recycled electronic elements (that is, the electronic elements EL), but not limited thereto. In some embodiments, the recycled electronic elements may serve as the repairing electronic elements in the electronic device ED.

It should be noted that the manufacturing method of the electronic device ED of the present embodiment is not limited to the contents mentioned above. In some embodiments, the step of breaking the first bonding elements BE1 may be performed three times to respectively separate the first light emitting elements LE1, the second light emitting elements LE2 and the third light emitting elements LE3 from the first substrate SB1 and transfer these light emitting elements to the temporary substrate TSB. In some embodiments, the temporary substrate TSB may include the magnetic elements ME but not the recess RS to attract the magnetic electronic elements EL. In some embodiments, the second bonding elements BE2 may be disposed on the electronic elements EL by laser dispensing.

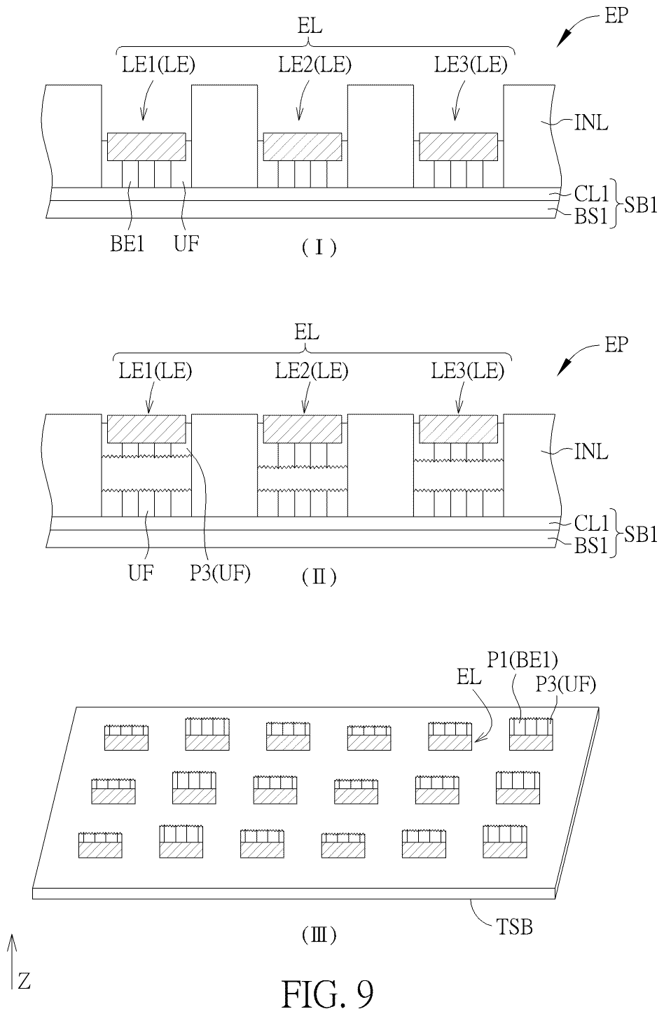

Referring to FIG. 9, FIG. 9 schematically illustrates a manufacturing process of an electronic device according to a fifth embodiment of the present disclosure. In the present embodiment, the electronic panel EP may further include an underfill material UF disposed between the electronic elements EL and the first substrate SB1. Specifically, as shown in the process (I) of FIG. 9, the underfill material UF may be filled in the openings OP defined by the insulating layer INL and is used for fixing the electronic elements EL. The underfill material UF may not cover the electronic element EL, or the underfill material UF may not cover the top surface of the electronic element EL. The underfill material UF may include any suitable insulating material, such as epoxy resin or acrylic resin, but not limited thereto.

After the underfill material UF is disposed in the electronic panel EP, if it is found that the first substrate SB1 in the electronic panel EP is a defective product after inspection, or the electronic panel EP becomes a defective product due to mistakes in subsequent process, the electronic elements EL may be debonded from the first substrate SB1, such that the electronic elements EL may be recycled, and the recycled electronic elements EL may be transferred to the second substrate SB2 of the electronic device ED. In an embodiment, the underfill material UF may not be removed before the step of debonding the electronic elements EL from the first substrate SB1. In such condition, as shown in the process (II) of FIG. 9, after the first bonding elements BE1 are broken, the portions P3 of the underfill material UF may be separated from the first substrate SB1 along with the electronic elements EL. After that, after the electronic elements EL are transferred to the temporary substrate TSB, as shown in the process (III) of FIG. 9, the portions P3 of the underfill material UF may be located on the electronic elements EL. That is, the remained portion P1 of the first bonding element BE1 and the portion P3 of the underfill material UF may be located on the electronic element EL. In such condition, after the electronic elements EL are transferred to the second substrate SB2, the portions P3 of the underfill material UF may be transferred to the second substrate SB2 along with the electronic elements EL, that is, the electronic device ED may include the portions P3 of the underfill material UF. It should be noted that the temporary substrate TSB shown in FIG. 9 is just exemplary, and the structure thereof may refer to the structure of the temporary substrate TSB in any embodiment above. In addition, the disposition way of the second bonding element BE2 and the method of transferring the electronic elements EL to the temporary substrate TSB may refer to the contents in any embodiment above.

In an embodiment, although it is not shown in the figure, the manufacturing method M100 may further include the step of removing the underfill material UF before the step of debonding the electronic elements EL from the first substrate SB1. For example, in the structure shown in the process (I) of FIG. 9, the underfill material UF may be removed through any suitable agent (for example, an agent that can decompose the material of the underfill material UF) at first, and then the electronic elements EL may be recycled through the method mentioned in any embodiment above, but not limited thereto. In some embodiments, the step of removing the underfill material UF may be performed after the electronic elements EL are transferred to the temporary substrate TSB (shown in the process (III) of FIG. 9).

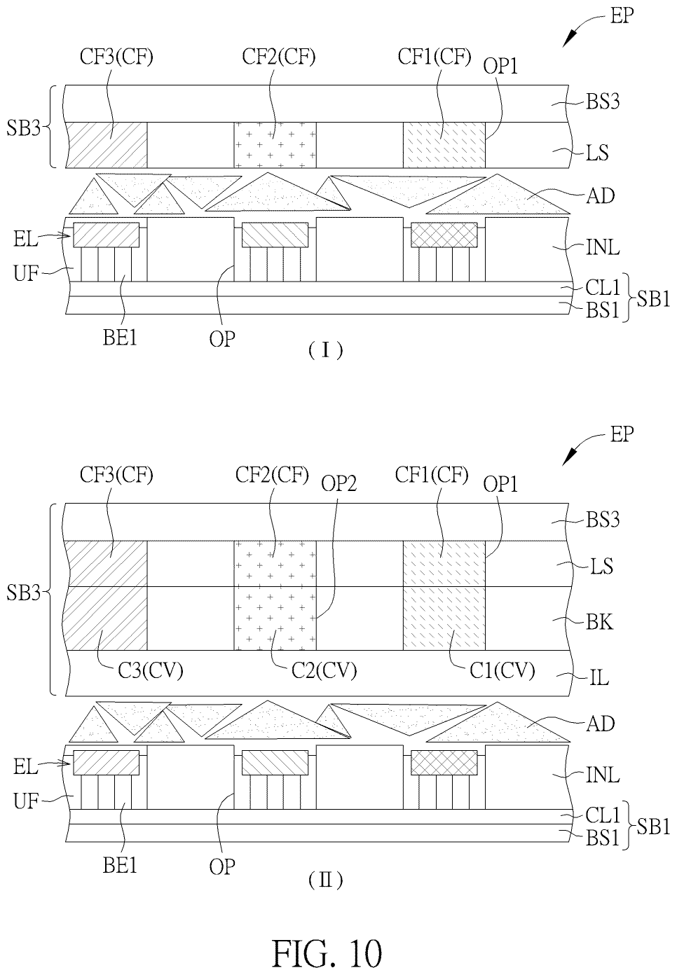

Referring to FIG. 10, FIG. 10 schematically illustrates a manufacturing process of an electronic device according to a sixth embodiment of the present disclosure. The electronic panel EP of the present embodiment may further include a third substrate SB3 and an adhesive layer AD, wherein the adhesive layer AD may include any suitable adhesive material, such as epoxy resin, but not limited thereto. The adhesive layer AD is used for attaching the third substrate SB3 to the first substrate SB1. As shown in the structure (I) and the structure (II) of FIG. 10, the third substrate SB3 may be disposed opposite to the first substrate SB1, and the adhesive layer AD and the electronic elements EL may be disposed between the first substrate SB1 and the third substrate SB3.

In an embodiment, as shown in the structure (I) of FIG. 10, the third substrate SB3 may include a base BS3 and a light shielding layer LS and a light filtering layer CF disposed on the base BS3. The light shielding layer LS may be disposed corresponding to the insulating layer INL of the first substrate SB1. The light filtering layer CF may be disposed corresponding to the electronic elements EL. The light filtering layer CF may include a plurality of light filtering units, such as the light filtering unit CF1, the light filtering unit CF2 and the light filtering unit CF3. The light filtering unit CF1, the light filtering unit CF2 and the light filtering unit CF3 may respectively correspond to an electronic element EL in an opening OP of the insulating layer INL. Specifically, the light shielding layer LS may include a black matrix layer and defines a plurality of openings OP1, and the light filtering unit CF1, the light filtering unit CF2 and the light filtering unit CF3 may respectively be disposed in one of the openings OP1. The light filtering layer CF includes any suitable element or layer that allows light of a specific wavelength to pass through, such as color filter, but not limited thereto. In other words, the third substrate SB3 for example includes a color filter substrate, but not limited thereto. In an embodiment, the light filtering unit CF1, the light filtering unit CF2 and the light filtering unit CF3 may respectively allow red light, blue light and green light to pass through, but not limited thereto. The light shielding layer LS may include any suitable light shielding material, such as black photoresist, black printing ink or black resin, but not limited thereto. The material of the base BS3 may refer to the material of the base BS1 mentioned above, but not limited thereto.

In an embodiment, as shown in the structure (II) of FIG. 10, the third substrate SB3 may further include a bank structure BK and an optical layer CV in addition to the elements and the layers mentioned above. The bank structure BK may be disposed corresponding to the light shielding layer LS. The optical layer CV may be disposed corresponding to the light filtering layer CF. The optical layer CV may include a plurality of optical units, such as the optical unit C1, the optical unit C2 and the optical unit C3. The optical unit C1, the optical unit C2 and the optical unit C3 may respectively correspond to the light filtering unit CF1, the light filtering unit CF2 and the light filtering unit CF3. Specifically, the bank structure BK may define a plurality of openings OP2, and the optical unit C1, the optical unit C2 and the optical unit C3 may respectively be disposed in one of the openings OP2. The optical layer CV may include any suitable material that may change the wavelength or color of light passing through the optical layer CV or may change the emitting angle of the light. The optical layer CV may include quantum dot, fluorescent, phosphorescent, scattering particles, other suitable materials or combinations of the above-mentioned materials. In an embodiment, the electronic elements EL may emit blue light, and in such condition, the optical unit C1 corresponding to red light filtering unit (such as the light filtering unit CF1) may convert the light passing through it into red light, the optical unit C3 corresponding to green light filtering unit (such as the light filtering unit CF3) may convert the light passing through it into green light, and the optical unit C2 corresponding to blue light filtering unit (such as the light filtering unit CF2) may include scattering particles for changing the emitting angle of the light, but not limited thereto. The bank structure BK may include any suitable light shielding material. In addition, the third substrate SB3 may further include an encapsulation layer IL disposed between the optical layer CV and the adhesive layer AD. The encapsulation layer IL may be used to reduce the possibility of water and oxygen intruding into the optical layer CV, thereby providing protection to the optical layer CV. Although the encapsulation layer IL is shown as a single layer in FIG. 10, it is not limited in the present embodiment. In some embodiments, the encapsulation layer IL may include a multi-layer structure, such as a structure formed by stacking multiple inorganic insulating layers or a structure formed by alternately stacking inorganic insulating layers and organic insulating layers.

The structure of the first substrate SB1 of the electronic panel EP of the present embodiment may refer to the contents in the embodiments above, and will not be redundantly described.

According to the present embodiment, after the first substrate SB1 and the third substrate SB3 are attached to each other through the adhesive layer AD to form the electronic panel EP, if bubbles appear between the first substrate SB1 and the third substrate SB3, the electronic panel EP is determined to be a defective product. In such condition, the manufacturing method M100 mentioned above may further include removing the adhesive layer AD to separate the first substrate SB1 and the third substrate SB3 before the step of debonding the electronic elements EL from the first substrate SB1. Specifically, the first substrate SB1 and the third substrate SB3 may be separated from each other by breaking the adhesive layer AD (as shown in the structure (I) and the structure (II) of FIG. 10). The adhesive layer AD may for example be broken by cryogenic freezing or other suitable methods. In some embodiments, after the adhesive layer AD is broken, the first substrate SB1 and the third substrate SB3 may be separated by further applying external force. After that, the electronic elements EL may be recycled from the first substrate SB1 through the methods described in the embodiments above and be used as the electronic elements in the electronic device ED.

In summary, the present disclosure provides a method for recycling electronic elements from a substrate scheduled to be scrapped, and using the recycled electronic elements as the electronic elements in another electronic device. Therefore, the production cost of the electronic device may be reduced, or carbon emissions may be reduced. In addition, the electronic elements in the electronic device formed through the above-mentioned method may have height difference, or the interface properties between the electronic elements and the bonding elements in the electronic device may be different.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising following steps:
(a) providing an electronic panel, wherein the electronic panel comprises a first substrate and a plurality of electronic elements, and the plurality of electronic elements are bonded on the first substrate;
(b) inspecting the electronic panel, wherein when the electronic panel is determined to be a defective product, perform following step (c) to step (f);
(c) debonding the plurality of electronic elements from the first substrate;
(d) transferring the plurality of electronic elements to a temporary substrate;
(e) transferring the plurality of electronic elements from the temporary substrate to a second substrate; and
(f) bonding the plurality of electronic elements on the second substrate.

2. The manufacturing method of claim 1, wherein the step of debonding the plurality of electronic elements from the first substrate comprises breaking a plurality of first bonding elements between the plurality of electronic elements and the first substrate.

3. The manufacturing method of claim 2, wherein breaking the plurality of first bonding elements between the plurality of electronic elements and the first substrate is performed by a laser process or an etching process.

4. The manufacturing method of claim 2, further comprising removing a portion of the plurality of first bonding elements remained on the plurality of electronic elements after transferring the plurality of electronic elements to the temporary substrate.

5. The manufacturing method of claim 1, wherein the plurality of electronic elements are transferred to the temporary substrate by fluid transfer or pick and place transfer.

6. The manufacturing method of claim 1, wherein the plurality of electronic elements comprise a ferromagnetic material, the temporary substrate comprises a plurality of magnetic elements respectively used for attracting the plurality of electronic elements.

7. The manufacturing method of claim 1, wherein the temporary substrate comprises a plurality of recesses respectively used for accommodating the plurality of electronic elements.

8. The manufacturing method of claim 7, wherein the plurality of electronic elements have at least two sizes, and the plurality of recesses of the temporary substrate have at least two sizes which are respectively used for accommodating the plurality of electronic elements having the at least two sizes.

9. The manufacturing method of claim 1, further comprising disposing a baffle above the first substrate before the step of debonding the plurality of electronic elements from the first substrate, wherein a distance between the baffle and the first substrate is less than 10 micrometers.

10. The manufacturing method of claim 1, further comprising forming a plurality of second bonding elements respectively on the plurality of electronic elements before the step of transferring the plurality of electronic elements from the temporary substrate to the second substrate.

11. The manufacturing method of claim 10, wherein the plurality of electronic elements are bonded on the second substrate through the plurality of second bonding elements.

12. The manufacturing method of claim 1, wherein the electronic panel further comprises an underfill material disposed between the plurality of electronic elements and the first substrate, and the manufacturing method further comprises removing the underfill material before the step of debonding the plurality of electronic elements from the first substrate.

13. The manufacturing method of claim 1, wherein the electronic panel further comprises a third substrate and an adhesive layer, the third substrate is disposed opposite to the first substrate, the adhesive layer and the plurality of electronic elements are disposed between the first substrate and the third substrate, and the manufacturing method further comprises removing the adhesive layer to separate the first substrate and the third substrate before the step of debonding the plurality of electronic elements from the first substrate.

14. An electronic device, comprising:
a substrate; and
a plurality of electronic elements bonded on the substrate, wherein the plurality of electronic elements comprise a first electronic element and a second electronic element, the first electronic element has a height Ha, the second electronic element has a height Hb, the height Hb is greater than the height Ha, and the height Ha and the height Hb satisfy:
0.05≤(Hb−Ha)/Hb≤1.1.

15. The electronic device of claim 14, wherein the height Ha and the height Hb satisfy:
0.10≤(Hb−Ha)/Hb≤1.1.

16. The electronic device of claim 14, wherein the height Ha and the height Hb satisfy:
0.05≤(Hb−Ha)/Hb≤0.55.

17. The electronic device of claim 14, wherein one of the first electronic element and the second electronic element is a non-recyclable electronic element, and another one of the first electronic element and the second electronic element is a recyclable electronic element.

18. The electronic device of claim 14, wherein the first electronic element and the second electronic element are recyclable electronic elements.

19. The electronic device of claim 14, wherein the plurality of electronic elements further comprise a third electronic element, the third electronic element has a height Hc, and a difference between the height Hc and the height Ha is less than a difference between the height Hc and the height Hb.

20. The electronic device of claim 19, wherein the first electronic element and the third electronic element are non-recyclable electronic elements, and the second electronic element is a recyclable electronic element.
